(19) United States
(12) Patent Application Publication
(10) Pub. No.: US 2015/0354054 A1
(43) Pub. Date: Dec. 10, 2015

(54) COOLED PROCESS TOOL ADAPTER FOR USE IN SUBSTRATE PROCESSING CHAMBERS

(71) Applicant: APPLIED MATERIALS, INC., Santa Clara, CA (US)

(72) Inventors: WILLIAM R. FRUCHTERMAN, Santa Clara, CA (US); MARTIN LEE RIKER, Milpitas, CA (US); KEITH A. MILLER, Mountain View, CA (US); ANTHONY INFANTE, San Mateo, CA (US)

(21) Appl. No.: 14/713,386

(22) Filed: May 15, 2015

Related U.S. Application Data
(60) Provisional application No. 62/009,153, filed on Jun. 6, 2014.

(51) Int. Cl. C23C 14/34

(52) U.S. Cl. CPC C23C 14/345

(57) ABSTRACT

Embodiments of cooled process tool adapters for use in substrate processing chambers are provided herein. In some embodiments, a cooled process tool adapter includes: an annular body surrounding a central opening; a coolant channel disposed in the annular body; one or more features to facilitate supporting a process tool within the central opening; an inlet and an outlet disposed in the annular body and fluidly coupled to the coolant channel; and a power connection coupled to the annular body having a terminal to couple the annular body to a bias power source.

### CROSS-REFERENCE TO RELATED APPLICATIONS

This application claims benefit of U.S. provisional patent application Ser. No. 62/009,153, filed Jun. 6, 2014, which is herein incorporated by reference in its entirety.

### FIELD

Embodiments of the present disclosure generally relate to substrate processing chambers used in semiconductor manufacturing systems.

### BACKGROUND

Reliably producing submicron and smaller features is one of the technologies for the next generation of very large scale integration (VLSI) and ultra large scale integration (ULSI) of semiconductor devices. However, as the miniaturization of circuit technology continues, the shrinking dimensions of interconnects in VLSI and ULSI technology have placed additional demands on the processing capabilities. For example, as circuit densities increase for next generation devices, the widths of interconnects, such as vias, trenches, contacts, gate structures and other features, as well as the dielectric materials therebetween, decrease while the thickness of the dielectric layers remains substantially constant, with the result of increasing the aspect ratios of the features.

Sputtering, also known as physical vapor deposition (PVD), is a method of forming metallic features in integrated circuits. Sputtering deposits a material layer on a substrate. A source material, such as a target, is bombarded by ions strongly accelerated by an electric field. The bombardment ejects material from the target, and the material then deposits on the substrate. During deposition, ejected particles may travel in varying directions, rather than generally orthogonal to the substrate surface, undesirably resulting in overhanging structures formed on corners of high aspect ratio features in the substrate. Overhang may undesirably result in holes or voids formed within the deposited material, resulting in diminished electrical conductivity of the formed feature. Higher aspect ratio geometries have a higher degree of difficulty to fill without voids.

Controlling the ion fraction or ion density reaching the substrate surface to a desired range may improve the bottom and sidewall coverage during the metal layer deposition process (and reduce the overhang problem). In one example, the particles dislodged from the target may controlled via a process tool such as a collimator to facilitate providing a more vertical trajectory of particles into the feature. The collimator provides relatively long, straight, and narrow passageways between the target and the substrate to filter out non-vertically travelling particles that impact and stick to the passageways of the collimator. To further control the ion fraction or ion density reaching the substrate surface, the collimator may be electrically biased. However, the inventors have observed that providing electrical bias of the collimator requires electrical isolation of the collimator from grounded surfaces of the process chamber, undesirably resulting in thermal isolation and excessive heating of the collimator, which further leads to reduced uptime of the process chamber.

Thus, the inventors have provided improved embodiments of apparatus for forming a metal containing layer with good bottom and sidewall management.

### SUMMARY

Embodiments of cooled process tool adapters for use in substrate processing chambers are provided herein. In some embodiments, a cooled process tool adapter includes: an annular body surrounding a central opening; a coolant channel disposed in the annular body; one or more features to facilitate supporting a process tool within the central opening; an inlet and an outlet disposed in the annular body and fluidly coupled to the coolant channel; and a power connection coupled to the annular body having a terminal to couple the annular body to a bias power source.

In some embodiments, a cooled process tool adapter includes: an annular body surrounding a central opening; a radially inwardly extending shelf disposed along an inner diameter of the annular body to facilitate supporting a process tool within the central opening; a plurality of through holes disposed through the shelf to facilitate coupling a process tool to the annular body; a coolant channel disposed in the annular body, wherein the coolant channel comprises a channel disposed along an outer diameter of the annular body and a cap disposed over the channel to seal the coolant channel; an inlet and an outlet disposed in the annular body and fluidly coupled to the coolant channel; and a power connection coupled to the annular body having a terminal to couple the annular body to a bias power source.

In some embodiments, a process chamber includes: a body including a ground adapter and a lid assembly partially defining an interior volume of the process chamber; a cooled process tool adapter having an annular body surrounding a central opening, wherein the central opening faces the interior volume of the process chamber; an insulator ring disposed between the cooled process tool adapter and the lid assembly; and an insulator ring disposed between the cooled process tool adapter and the ground adapter. The cooled process tool adapter further includes: a coolant channel disposed in the annular body; an inlet and an outlet disposed in the annular body and fluidly coupled to the coolant channel; and a power connection coupled to the annular body having a terminal to couple the annular body to a bias power source.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic cross-sectional view of a process chamber in accordance with the some embodiments of the present disclosure.

FIG. 2 depicts a top view of a collimator in accordance with some embodiments of the present disclosure.

FIG. 3 depicts a perspective view of a cooled process tool adapter in accordance with some embodiments of the present disclosure.

FIGS. 4A-B respectively depict side cross-sectional views of the cooled process tool adapter of FIG. 3, taken along section lines 4A-4A and 4B-4B as illustrated in FIG. 3.

FIG. 5 depicts a partial cross-sectional detail view of a deposition chamber and cooled process tool adapter in accordance with some embodiments of the present disclosure.

FIG. 6 depicts a schematic partial view of coolant connections to a cooled process tool adapter in a deposition chamber in accordance with some embodiments of the present disclosure.

FIG. 7 is an exploded view of a deposition chamber having a cooled process tool adapter in accordance with the some embodiments of the present disclosure.

To facilitate understanding, identical reference numerals have been used, where possible, to designate identical elements that are common to the figures. The figures are not drawn to scale and may be simplified for clarity. Elements and features of some embodiments may be beneficially incorporated in other embodiments without further recitation.

### DETAILED DESCRIPTION

Embodiments of cooled process tool adapters for use in substrate processing systems, such as those used for microelectronic device fabrication on semiconductor substrates, are provided herein. Cooled process tool adapters as disclosed herein advantageously increase operation time of process tools in a plasma by removing heat transferred from the plasma to the process tools. The cooled process tool adapter may advantageously be used to couple various types of process tools to a substrate processing chamber. For example, in some embodiments a process tool, such as a biased collimator, may be coupled to the cooled process tool adapter, advantageously allowing the biased collimator to operate longer.

Embodiments of the present disclosure provide a process tool adapter having cooling channels disposed on an atmospheric pressure side of the adapter to facilitate continuous cooling. A flange is disposed along a vacuum side of the adapter to allow for different process tools (such as a biased collimator) to be connected to the adapter and cooled via the adapter. In some embodiments, vacuum seals may be provided to allow the inside of the adapter to operate at vacuum pressures, such as up to ultra-high vacuum pressures. In some embodiments, a bias connection is provided to allow the adapter, and any process tool attached to the adapter, to be operated with a bias voltage applied by a bias generator, for example, to condition the plasma. In some embodiments, an RF filter box may be provided to remove RF signals from the bias voltage returned to the bias generator. Heat generated during processing within the substrate processing chamber is transferred to the coolant flowing through the cooling channels in the process tool adapter.

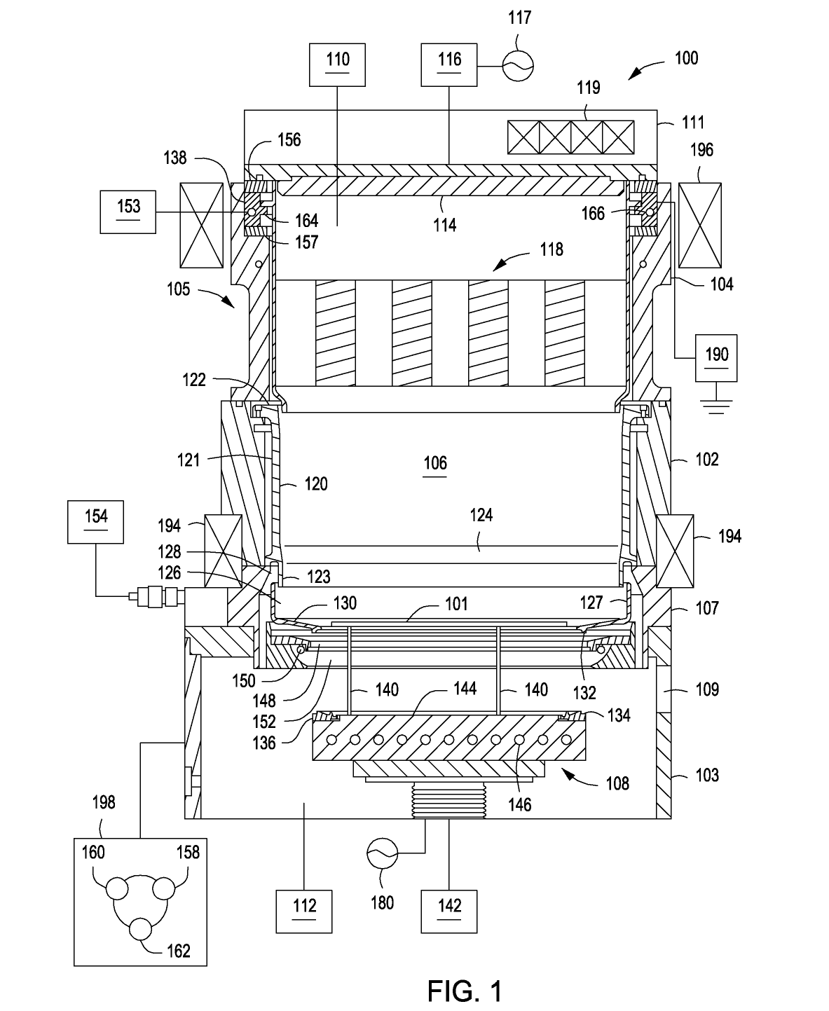

Embodiments of the present disclosure are illustratively described herein with respect to a physical vapor deposition (PVD) chamber. However, the cooled process tool adaptor may generally be used in any substrate processing chamber where process tools are used that need to be supported within the substrate processing chamber and cooled. FIG. 1 illustrates a PVD chamber (deposition chamber 100), e.g., a sputter process chamber, suitable for sputter depositing materials and having a collimator 118 disposed therein and supported by a cooled process tool adapter 138 in accordance with embodiments of the present disclosure. Illustrative examples of suitable PVD chambers that may be adapted to benefit from the disclosure include the ALPS® Plus and SIP ENCORE® PVD processing chambers, both commercially available from Applied Materials, Inc., Santa Clara, of California. Other processing chambers available from Applied Materials, Inc. as well as other manufacturers may also be adapted in accordance with the embodiments described herein.

The deposition chamber 100 has an upper sidewall 102, a lower sidewall 103, a ground adapter 104, and a lid assembly 111 defining a body 105 that encloses an interior volume 106 thereof. An adapter plate 107 may be disposed between the upper sidewall 102 and the lower sidewall 103. A substrate support, such as a pedestal 108, is disposed in the interior volume 106 of the deposition chamber 100. A substrate transfer port 109 is formed in the lower sidewall 103 for transferring substrates into and out of the interior volume 106.

In some embodiments, the deposition chamber 100 is a sputtering chamber, also known as a physical vapor deposition (PVD) chamber, capable of depositing, for example, titanium, aluminum oxide, aluminum, aluminum oxynitride, copper, tantalum, tantalum nitride, tantalum oxynitride, titanium oxynitride, tungsten, or tungsten nitride on a substrate, such as the substrate 101.

A gas source 110 is coupled to the deposition chamber 100 to supply process gases into the interior volume 106. In some embodiments, process gases may include inert gases, non-reactive gases, and reactive gases, if necessary. Examples of process gases that may be provided by the gas source 110 include, but not limited to, argon gas (Ar), helium (He), neon gas (Ne), nitrogen gas (N2), oxygen gas (O2), and H2O among others.

A pumping device 112 is coupled to the deposition chamber 100 in communication with the interior volume 106 to control the pressure of the interior volume 106. In some embodiments, the pressure level of the deposition chamber 100 may be maintained at about 1 Torr or less. In some embodiments, the pressure level of the deposition chamber 100 may be maintained at about 500 mTorr or less. In some embodiments, the pressure level of the deposition chamber 100 may be maintained at about 1 mTorr and about 300 mTorr.

The ground adapter 104 may support a sputtering source 114, such as a target. In some embodiments, the sputtering source 114 may be fabricated from a material containing titanium (Ti) metal, tantalum metal (Ta), tungsten (W) metal, cobalt (Co), nickel (Ni), copper (Cu), aluminum (Al), alloys thereof, combinations thereof, or the like. In some embodiments, the sputtering source 114 may be fabricated from titanium (Ti) metal, tantalum metal (Ta) or aluminum (Al).

The sputtering source 114 may be coupled to a source assembly 116 comprising a power supply 117 for the sputtering source 114. A magnetron assembly 119 which includes set of magnets may be coupled adjacent to the sputtering source 114 which enhances efficient sputtering materials from the sputtering source 114 during processing. Examples of the magnetron assembly include an electromagnetic linear magnetron, a serpentine magnetron, a spiral magnetron, a double-digitated magnetron, a rectangularized spiral magnetron, among others.

In some embodiments, a first set of magnets 194 may be disposed between the adapter plate 107 and the upper sidewall 102 to assist generating a magnetic field to guide the metallic ions dislodged from the sputtering source 114. A second set of magnets 196 may be disposed adjacent to the ground adapter 104 to assist generating the magnetic field to guide dislodged materials from the sputtering source 114. The numbers of the magnets disposed around the deposition chamber 100 may be selected to control plasma dissociation and sputtering efficiency.

An RF power source 180 may be coupled to the deposition chamber 100 through the pedestal 108 to provide a bias power between the sputtering source 114 and the pedestal 108. In some embodiments, the RF power source 180 may have a frequency between about 400 Hz and about 60 MHz, such as about 13.56 MHz.

A collimator 118, or other process tool, may be positioned in the interior volume 106 between the sputtering source 114 and the pedestal 108. The collimator 118 may be electrically biased to control ion flux to the substrate and neutral angular distribution at the substrate, as well as to increase the deposition rate due to the added DC bias. The inventors have discovered that electrically biasing the collimator results in reduced ion loss to the collimator to advantageously enable greater ion/neutral ratios at the substrate.

In some embodiments, the collimator 118 may be electrically biased in bipolar mode so as to control the direction of the ions passing through the collimator 118. For example, a controllable direct current (DC) or AC collimator power source 190 may be coupled to the collimator 118 to provide an alternating pulsed positive or negative voltage to the collimator 118 so as to bias the collimator 118. In some embodiments, the collimator power source 190 is a DC power source.

To facilitate applying bias to the collimator 118, the collimator 118 is electrically isolated from grounded chamber components such as the ground adapter 104. For example, in the embodiment depicted in FIG. 1, the collimator 118 is coupled to the cooled process tool adapter 138. The cooled process tool adapter 138 may be made from suitable conductive materials compatible with processing conditions in the deposition chamber 100. An insulator ring 156 and an insulator ring 157 are disposed on either side of the cooled process tool adapter 138 to electrically isolate the cooled process tool adapter 138 from the ground adapter 104. The insulator rings 156, 157 may be made from suitable process compatible dielectric materials.

The cooled process tool adapter 138 includes one or more features to facilitate supporting a process tool within the interior volume 106, such as the collimator 118. For example, as shown in FIG. 1, the cooled process tool adapter 138 includes a mounting ring, or shelf 164 that extends in a radially inward direction to support the collimator 118, or other process tool to be supported in the interior volume 106 of deposition chamber 100. In some embodiments, the mounting ring or shelf 164 is a continuous ring about the inner diameter of the cooled process tool adapter 138 to facilitate more uniform thermal contact with the process tool mounted to the cooled process tool adapter 138 (e.g., the collimator 118).

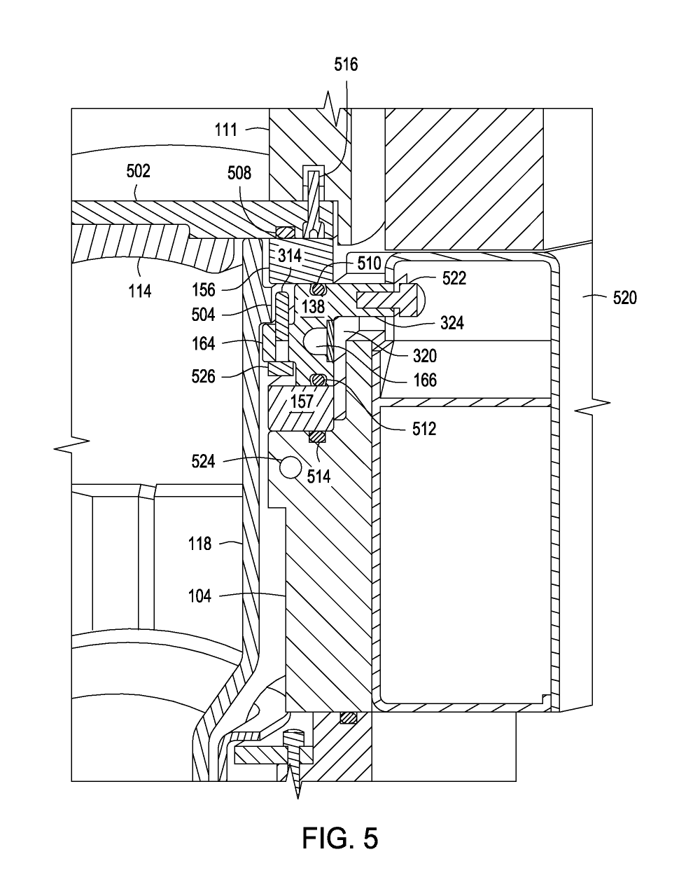

A coolant channel 166 is provided in the cooled process tool adapter 138 to facilitate flowing a coolant through the cooled process tool adapter 138 to remove heat generated during processing. For example, the coolant channel 166 may be coupled to a coolant source 153 to provide a suitable coolant, such as water. The coolant channel 166 advantageously removes heat from the process tool (e.g., collimator 118) that is not readily transferred to other cooled chamber components, such as the ground adapter 104. For example, the insulator rings 156, 157 disposed between the cooled process tool adapter 138 and the ground adapter 104 are typically made from materials with poor thermal conductivity. Thus, the insulator rings 156, 157 reduce the rate of heat transfer from the collimator 118 to the ground adapter 104 and the cooled process tool adapter 138 advantageously maintains or increases the rate of cooling of the collimator 118. In addition to the coolant channel 166 provided in the cooled process tool adapter 138, the ground adapter 104 may also include a coolant channel (such as coolant channel 524 depicted in FIG. 5) to further facilitate removing heat generated during processing.

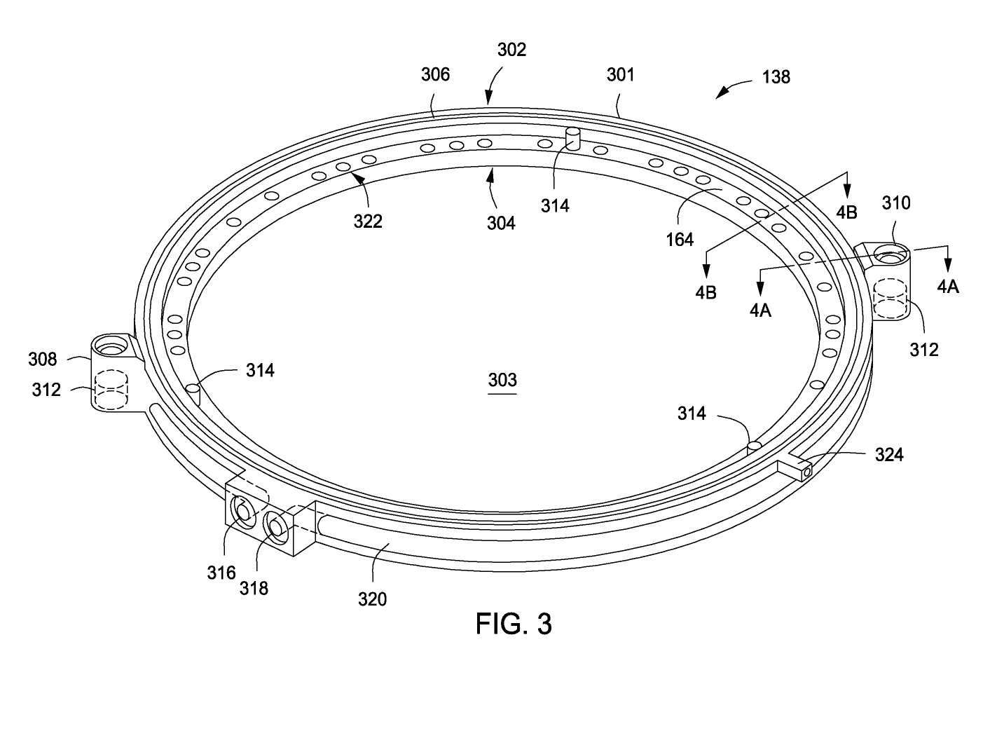

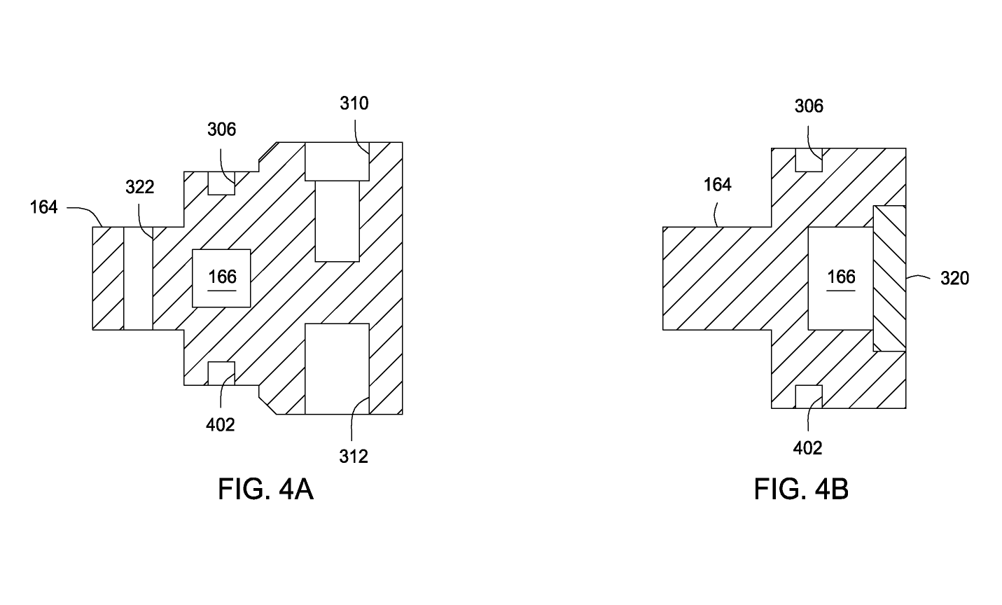

FIG. 3 depicts a perspective view of the cooled process tool adapter 138 in accordance with some embodiments of the present disclosure. FIGS. 4A-B respectively depict side cross-sectional views of the cooled process tool adapter 138 taken along section lines 4A-4A and 4B-4B, as shown in FIG. 3. The cooled process tool adapter 138 includes an annular body 301 defining a central opening 303. The annular body 301 includes a generally planar upper surface 302 and an opposing generally planar lower surface 304. In some embodiments, an annular groove 306 may be provided along the upper surface 302 to receive a seal such as an O-ring or other sealing gasket to facilitate forming a vacuum tight seal between the cooled process tool adapter 138 and insulator ring 156. Similarly, in some embodiments, an annular groove 402 (shown in FIGS. 4A-B) may be provided along the lower surface 304 to facilitate forming a vacuum tight seal between the cooled process tool adapter 138 and the insulator ring 157. Alternatively, either or both of the annular grooves 306, 402 may be formed in respective opposing surfaces of the insulator ring 156 or the insulator ring 157. Alternatively, either or both of the annular grooves 306, 402 may be formed partially in each of the cooled process tool adapter 138 and insulator ring 156, 157. Alternatively, if a vacuum seal can otherwise be provided between the cooled process tool adapter 138 and each of the insulator rings 156, 157, no grooves are necessary.

A radially inwardly extending ledge (e.g., the mounting ring, or shelf 164) is provided to support the collimator 118, as shown in FIG. 1, within the central opening 303 (e.g., within the interior volume 106 of the deposition chamber). The shelf 164 may extend inward from any location between the lower surface 304 the upper surface 302 of the annular body 301. However, in some embodiments the shelf 164 is disposed in a location proximate the coolant channel 166 to facilitate maximizing the heat transfer from the collimator 118 to the coolant flowing in the coolant channel 166 during use.

A plurality of through holes 322 may be disposed through the shelf 164 to facilitate coupling the collimator 118 to the cooled process tool adapter 138. In some embodiments, some of the through holes of the plurality of through holes 322 may be used to capture and align a nut plate (e.g., nut plate 526 shown in FIG. 5) with respect to the shelf 164 and the remaining through holes of the plurality of through holes 322. Some or all of the remaining through holes of the plurality of through holes 322 may be used to fasten the collimator 118 to the shelf 164 of the cooled process tool adapter 138.

One or more alignment pins 314 may be provided to facilitate alignment of the collimator 118 to the cooled process tool adapter 138. In some embodiments, and as shown in FIG. 3, three alignment pins 314 may be provided. The alignment pins 314 facilitate centering and orientation of the collimator 118 with respect to the cooled process tool adapter 138.

In addition, a plurality of orientation features 308 may also be provided on the cooled process tool adapter 138 to facilitate centering and orientation of the cooled process tool adapter 138, and hence the collimator 118, with respect to the ground adapter 104, and hence the interior volume 106 of the deposition chamber 100. In some embodiments, the plurality of orientation features include an upper alignment feature to align the cooled process tool adapter with components disposed above the cooled process tool adapter and an lower alignment feature to align the cooled process tool adapter with components disposed above the cooled process tool adapter. For example, each orientation feature 308 may include an upper opening 310 to interface with a locating pin extending from the lid assembly 111 and a lower opening 312 to interface with the locating pin extending from the ground adapter 104. In some embodiments, and as depicted in FIG. 3, a pair of diametrically opposed orientation features 308 are provided.

The coolant channel 166 generally circumscribes the annular body 301 and includes an inlet 318 and an outlet 316. In some embodiments, the coolant channel 166 may be formed by forming a channel along an outer diameter of the annular body 301 and providing a cap 320 about the outer diameter of the annular body 301 and over the channel to seal the coolant channel 166 (for example, by welding). FIGS. 4B and 5 also illustrate the coolant channel 166 and cap 320. Providing the coolant channel along the outer diameter of the annular body 301 advantageously keeps potential water leaks away from the vacuum side of the cooled process tool adapter 138.

A power connection 324 may be disposed along the annular body 301 to facilitate providing power to the collimator power source 190 and provide bias power to the collimator 118 or other process tool coupled to the cooled process tool adapter 138. In some embodiments, the power connection 324 extends radially outward from the annular body 301.

FIG. 5 depicts a partial cross-sectional detail view of the deposition chamber 100 and cooled process tool adapter 138 in accordance with some embodiments of the present disclosure. As shown in FIG. 5, the cooled process tool adapter 138 is disposed between the sputtering source 114 and the ground adapter 104. In some embodiments, the sputtering source 114 includes a target of material to be sputtered supported by a target backing plate 502 and is coupled to the lid assembly 111 of the deposition chamber 100 via a fastener 516, such as a bolt. The Insulator ring 156 is disposed between the cooled process tool adapter 138 and the target backing plate 502 of the sputtering source 114. The insulator ring 157 is disposed between the cooled process tool adapter 138 and the ground adapter 104.

To maintain vacuum pressure in the interior volume 106 during use, one or more vacuum seals, such as o-rings, gaskets, or the like, may be provided between adjacent components where vacuum pressure is to be maintained on one side of the components and higher pressures, such as atmospheric pressure, are present on the other side of the components. For example, as depicted in FIG. 5, vacuum seals, 508, 510, 512, and 514 are disposed between adjacent components.

Vacuum seal 508 is provided between the target backing plate 502 and the insulator ring 156. Vacuum seal 510 is provided between the insulator ring 156 and the cooled process tool adapter 138. Vacuum seal 512 is provided between the cooled process tool adapter 138 and the insulator ring 157. Vacuum seal 514 is disposed between the insulator ring 157 and the ground adapter 104.

The collimator 118 is supported within the interior volume 106 of the deposition chamber 100 by the shelf 164 of the cooled process tool adapter. FIG. 5 depicts, the nut plate 526 disposed on a lower portion of the shelf 164 to facilitate fastening or bolting the outwardly extending flange 504 of the collimator 118 to the cooled process tool adapter 138. The alignment pin 314 is disposed in a mating alignment feature formed in the outwardly extending flange 504 of the collimator 118.

A power box 520 may be provided to facilitate coupling the collimator power source 190 to the cooled process tool adapter 138 via the power connection 324. For example, the power connection 324 may include a terminal for coupling a conductor from the power box 520 to the power connection 324 for example using a screw or bolt 522. The power box 520 may also include an RF filter to reduce or prevent RF signals accumulated on the collimator 118 in the plasma from infiltrating into the collimator power source 190. The power box 520 may also include connections for coupling the second set of magnets 196 (e.g., electromagnets) to an electromagnet power source.

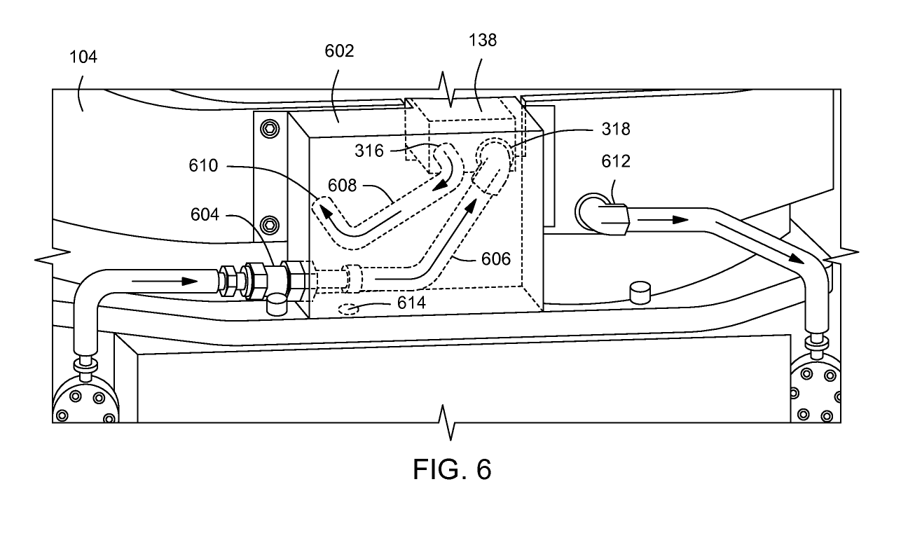

FIG. 6 depicts a schematic partial view of coolant connections to the cooled process tool adapter 138 of the deposition chamber 100 in accordance with some embodiments of the present disclosure. In some embodiments, the coolant connections to the cooled process tool adapter 138 may be disposed within a coolant connection housing 602, advantageously protecting operators or others outside of the deposition chamber 100 from electrical shock. A coolant supply may be coupled to a supply inlet 604 in the coolant connection housing 602. An inlet connector 606 is used to connect the supply inlet 604 to the inlet 318 of the cooled process tool adapter 138. In use, coolant flows around the coolant channel 166 from the inlet 318 to the outlet 316. In some embodiments, the coolant channel 524 of the ground adapter 104 and the coolant channel 166 of the cooled process tool adapter 138 may be fluidly coupled in series. As such, an outlet connector 608 may be disposed between the outlet 316 and a ground adapter inlet 610 to supply the coolant from the coolant channel 166 to the coolant channel 524 of the ground adapter 104. The inlet connector 606, inlet 318, outlet 316, outlet connector 608, and ground adapter inlet 610 may all be protected by (e.g., disposed within or covered by) the coolant connection housing 602. During use, the coolant flows around the coolant channel 524 of the ground adapter 104 and out of a ground adapter outlet 612 to a coolant return. The ground adapter outlet 612 need not be enclosed by the coolant connector housing 602 as the coolant is at ground potential upon leaving the ground adapter 104. A leak detector 614 may be provided in a lower portion of the coolant connection housing 602. In some embodiments, the leak detector 614 may be a small hole in a lower portion of the coolant connection housing 602 where any leaking coolant may collect.

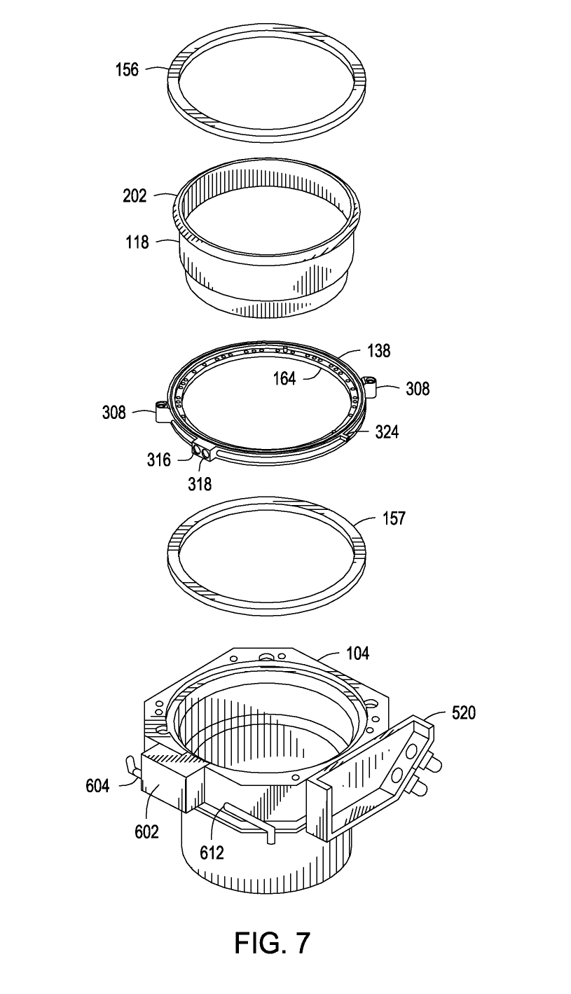

FIG. 7 is an exploded view of the deposition chamber 100 and the cooled process tool adapter 138 in accordance with the some embodiments of the present disclosure illustrating the position of the various components of the deposition chamber 100.

Returning to FIG. 1, in some embodiments, a shield tube 120 may be provided in proximity to the collimator 118 and interior of the ground adapter 104 or the upper sidewall 102. The collimator 118 includes a plurality of apertures to direct gas and/or material flux within the interior volume 106. The collimator 118 may be mechanically and electrically coupled to the shield tube 120. In some embodiments, the collimator 118 is mechanically coupled to the shield tube 120, such as by a welding process, making the collimator 118 integral to the shield tube 120. The collimator 118 may be coupled to an electrical power source via a cooled process tool adapter 138.

The shield tube 120 may include a tubular body 121 having a radially outwardly extending flange 122 disposed in an upper surface of the tubular body 121. The flange 122 provides a mating interface with an upper surface of the upper sidewall 102. In some embodiments, the tubular body 121 of the shield tube 120 may include a shoulder region 123 having an inner diameter that is less than the inner diameter of the remainder of the tubular body 121. In some embodiments, the inner surface of the tubular body 121 transitions radially inward along a tapered surface 124 to an inner surface of the shoulder region 123. A shield ring 126 may be disposed in the deposition chamber 100 adjacent to the shield tube 120 and intermediate of the shield tube 120 and the adapter plate 107. The shield ring 126 may be at least partially disposed in a recess 128 formed by an opposing side of the shoulder region 123 of the shield tube 120 and an interior sidewall of the adapter plate 107.

In some embodiments, the shield ring 126 may include an axially projecting annular sidewall 127 that has an inner diameter that is greater than an outer diameter of the shoulder region 123 of the shield tube 120. A radial flange 130 extends from the annular sidewall 127. The radial flange 130 may be formed at an angle greater than about ninety degrees (90°) relative to the inside diameter surface of the annular sidewall 127 of the shield ring 126. The radial flange 130 includes a protrusion 132 formed on a lower surface of the radial flange 130. The protrusion 132 may be a circular ridge extending from the surface of the radial flange 130 in an orientation that is substantially parallel to the inside diameter surface of the annular sidewall 127 of the shield ring 126. The protrusion 132 is generally adapted to mate with a recess 134 formed in an edge ring 136 disposed on the pedestal 108. The recess 134 may be a circular groove formed in the edge ring 136. The engagement of the protrusion 132 and the recess 134 centers the shield ring 126 with respect to the longitudinal axis of the pedestal 108. The substrate 101 (shown supported on lift pins 140) is centered relative to the longitudinal axis of the pedestal 108 by coordinated positioning calibration between the pedestal 108 and a robot blade (not shown). Thus, the substrate 101 may be centered within the deposition chamber 100 and the shield ring 126 may be centered radially about the substrate 101 during processing.

In operation, a robot blade (not shown) having the substrate 101 disposed thereon is extended through the substrate transfer port 109. The pedestal 108 may be lowered to allow the substrate 101 to be transferred to the lift pins 140 extending from the pedestal 108. Lifting and lowering of the pedestal 108 and/or the lift pins 140 may be controlled by a drive 142 coupled to the pedestal 108. The substrate 101 may be lowered onto a substrate receiving surface 144 of the pedestal 108. With the substrate 101 positioned on the substrate receiving surface 144 of the pedestal 108, sputter deposition may be performed on the substrate 101. The edge ring 136 may be electrically insulated from the substrate 101 during processing. Therefore, the substrate receiving surface 144 may include a height that is greater than a height of portions of the edge ring 136 adjacent the substrate 101 such that the substrate 101 is prevented from contacting the edge ring 136. During sputter deposition, the temperature of the substrate 101 may be controlled by utilizing thermal control channels 146 disposed in the pedestal 108.

After sputter deposition, the substrate 101 may be elevated utilizing the lift pins 140 to a position that is spaced away from the pedestal 108. The elevated location may be proximate one or both of the shield ring 126 and a reflector ring 148 adjacent to the adapter plate 107. The adapter plate 107 includes one or more lamps 150 coupled to the adapter plate 107 at a position intermediate of a lower surface of the reflector ring 148 and a concave surface 152 of the adapter plate 107. The lamps 150 provide optical and/or radiant energy in the visible or near visible wavelengths, such as in the infra-red (IR) and/or ultraviolet (UV) spectrum. The energy from the lamps 150 is focused radially inward toward the backside (i.e., lower surface) of the substrate 101 to heat the substrate 101 and the material deposited thereon. Reflective surfaces on the chamber components surrounding the substrate 101 serve to focus the energy toward the backside of the substrate 101 and away from other chamber components where the energy would be lost and/or not utilized. The adapter plate 107 may be coupled to the coolant source 153 to control the temperature of the adapter plate 107 during heating.

After controlling the substrate 101 to a predetermined temperature, the substrate 101 is lowered to a position on the substrate receiving surface 144 of the pedestal 108. The substrate 101 may be rapidly cooled utilizing the thermal control channels 146 in the pedestal 108 via conduction. The temperature of the substrate 101 may be ramped down from the first temperature to a second temperature in a matter of seconds to about a minute. The substrate 101 may be removed from the deposition chamber 100 through the substrate transfer port 109 for further processing. The substrate 101 may be maintained at a predetermined temperature range, such as less than 250 degrees Celsius.

A controller 198 is coupled to the deposition chamber 100. The controller 198 includes a central processing unit (CPU) 160, a memory 158, and support circuits 162. The controller 198 is utilized to control the process sequence, regulating the gas flows from the gas source 110 into the deposition chamber 100 and controlling ion bombardment of the sputtering source 114. The CPU 160 may be of any form of a general purpose computer processor that can be used in an industrial setting. The software routines can be stored in the memory 158, such as random access memory, read only memory, floppy or hard disk drive, or other form of digital storage. The support circuits 162 are conventionally coupled to the CPU 160 and may comprise cache, clock circuits, input/output subsystems, power supplies, and the like. The software routines, when executed by the CPU 160, transform the CPU into a specific purpose computer (controller) 198 that controls the deposition chamber 100 such that the processes are performed in accordance with embodiments of the present disclosure. The software routines may also be stored and/or executed by a second controller (not shown) that is located remotely from the deposition chamber 100.

During processing, material is sputtered from the sputtering source 114 and deposited on the surface of the substrate 101. The sputtering source 114 and the pedestal 108 are biased relative to each other by the power supply 117 or the RF power source 180 to maintain a plasma formed from the process gases supplied by the gas source 110. The DC pulsed bias power applied to the collimator 118 also assists controlling ratio of the ions and neutrals passing through the collimator 118, advantageously enhancing the trench sidewall and bottom fill-up capability. The ions from the plasma are accelerated toward and strike the sputtering source 114, causing target material to be dislodged from the sputtering source 114. The dislodged target material and process gases forms a layer on the substrate 101 with desired compositions.

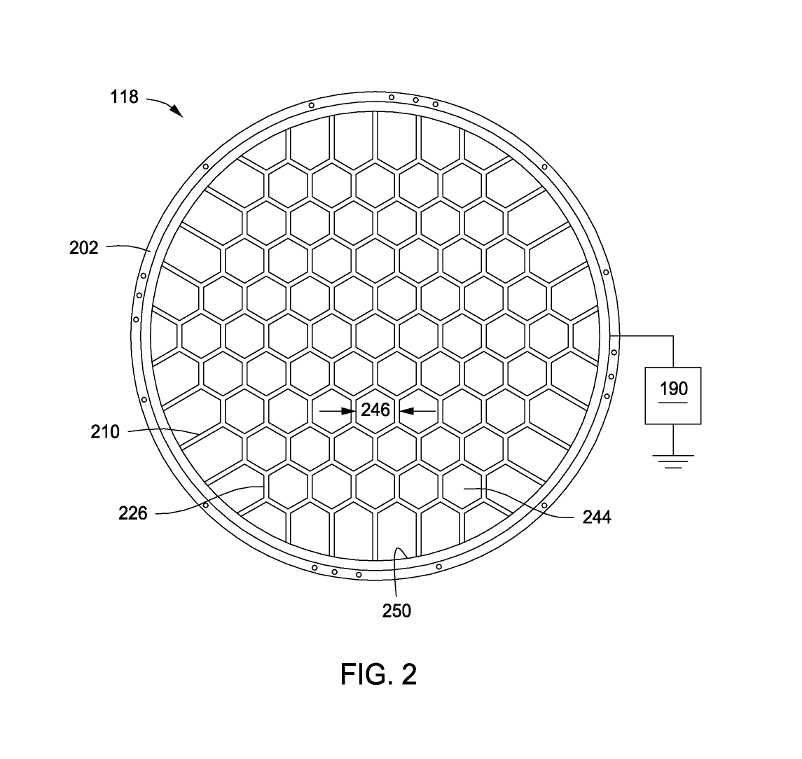

FIG. 2 depicts a top view of the collimator 118 coupled to the collimator power source 190 that may be disposed in the deposition chamber 100 of FIG. 1. In some embodiments, the collimator 118 has a generally honeycomb structure having hexagonal walls 226 separating hexagonal apertures 244 in a close-packed arrangement. However, other geometric configurations may also be used. An aspect ratio of the hexagonal apertures 244 may be defined as the depth of the aperture 244 (equal to the length of the collimator) divided by the width 246 of the aperture 244. In some embodiments, the thickness of the walls 226 is about 0.06 inches to about 0.18 inches. In some embodiments, the thickness of the walls 226 is about 0.12 inches to about 0.15 inches. In some embodiments, the collimator 118 is comprised of a material selected from aluminum, copper, and stainless steel.

The honeycomb structure of the collimator 118 may serve as an integrated flux optimizer 210 to optimize the flow path, ion fraction, and ion trajectory behavior of ions passing through the collimator 118. In some embodiments, the hexagonal walls 226 adjacent to a shield portion 202 have a chamfer 250 and a radius. The shield portion 202 of the collimator 118 may assist installing the collimator 118 into the deposition chamber 100.

In some embodiments, the collimator 118 may be machined from a single mass of aluminum. The collimator 118 may optionally be coated or anodized. Alternatively, the collimator 118 may be made from other materials compatible with the processing environment, and may also be comprised of one or more sections. Alternatively, the shield portion 202 and the integrated flux optimizer 210 are formed as separate pieces and coupled together using suitable attachment means, such as welding.

The collimator 118 functions as a filter to trap ions and neutrals that are emitted from the material from the sputtering source 114 at angles exceeding a selected angle, near normal relative to the substrate 101. The collimator 118 may have an aspect ratio change across the width of the collimator 118 to allow a different percentage of ions emitted from a center or a peripheral region of the material from the sputtering source 114 to pass through the collimator 118. As a result, both the number of ions and the angle of arrival of ions deposited onto peripheral regions and center regions of the substrate 101 are adjusted and controlled. Therefore, material may be more uniformly sputter deposited across the surface of the substrate 101. Additionally, material may be more uniformly deposited on the bottom and sidewalls of high aspect ratio features, particularly high aspect ratio vias and trenches located near the periphery of the substrate 101.

Thus, embodiments of a cooled process tool adapter and process chambers using same have been disclosed herein. The cooled process tool adapter advantageously facilitates supporting a process tool in a process chamber while removing heat from the process tool generated during use.

While the foregoing is directed to embodiments of the present disclosure, other and further embodiments of the disclosure may be devised without departing from the basic scope thereof.

1. A cooled process tool adapter, comprising:
an annular body surrounding a central opening;
a coolant channel disposed in the annular body;
one or more features to facilitate supporting a process tool within the central opening;
an inlet and an outlet disposed in the annular body and fluidly coupled to the coolant channel; and
a power connection coupled to the annular body having a terminal to couple the annular body to a bias power source.

2. The cooled process tool adapter of claim 1, wherein the one or more features to facilitate supporting the process tool comprise a radially inwardly extending shelf disposed along an inner diameter of the annular body.

3. The cooled process tool adapter of claim 2, further comprising:
a plurality of through holes disposed through the shelf to facilitate coupling a process tool to the annular body.

4. The cooled process tool adapter of claim 2, further comprising:
one or more alignment pins to facilitate aligning a process tool to the cooled process tool adapter.

5. The cooled process tool adapter of claim 4, wherein the one or more alignment pins are three alignment pins.

6. The cooled process tool adapter of claim 1, wherein the annular body further comprises a substantially planar upper surface and a substantially planar lower surface.

7. The cooled process tool adapter of claim 6, further comprising:
an annular groove disposed along the substantially planar upper surface; and
an annular groove disposed along the substantially planar lower surface.

8. The cooled process tool adapter of claim 1, wherein the coolant channel comprises:
a channel disposed along an outer diameter of the annular body; and
a cap disposed over the channel to seal the coolant channel.

9. The cooled process tool adapter of claim 1, further comprising:
a plurality of orientation features to facilitate centering and orientation of the cooled process tool adapter with respect to a process chamber in which the cooled process tool adapter is to be installed.

10. The cooled process tool adapter of claim 9, wherein the plurality of orientation features further comprise:
an upper alignment feature to align the cooled process tool adapter with components disposed above the cooled process tool adapter; and
an lower alignment feature to align the cooled process tool adapter with components disposed above the cooled process tool adapter.

11. The cooled process tool adapter of claim 9, wherein the plurality of orientation features are two diametrically opposed orientation features.

12. A cooled process tool adapter, comprising:
an annular body surrounding a central opening;
a radially inwardly extending shelf disposed along an inner diameter of the annular body to facilitate supporting a process tool within the central opening;
a plurality of through holes disposed through the shelf to facilitate coupling a process tool to the annular body
a coolant channel disposed in the annular body, wherein the coolant channel comprises a channel disposed along an outer diameter of the annular body and a cap disposed over the channel to seal the coolant channel;
an inlet and an outlet disposed in the annular body and fluidly coupled to the coolant channel; and
a power connection coupled to the annular body having a terminal to couple the annular body to a bias power source.

13. A process chamber, comprising:
a body including a ground adapter and a lid assembly partially defining an interior volume of the process chamber;
a cooled process tool adapter having an annular body surrounding a central opening, wherein the central opening faces the interior volume of the process chamber, and wherein the cooled process tool adapter further comprises:
a coolant channel disposed in the annular body;
an inlet and an outlet disposed in the annular body and fluidly coupled to the coolant channel; and
a power connection coupled to the annular body having a terminal to couple the annular body to a bias power source;
an insulator ring disposed between the cooled process tool adapter and the lid assembly; and
an insulator ring disposed between the cooled process tool adapter and the ground adapter.

14. The process chamber of claim 13, further comprising:
a coolant connector housing enclosing the inlet and the outlet of the cooled process tool adapter and having a supply inlet to couple to a coolant source.

15. The process chamber of claim 14, wherein the coolant connector housing further comprises a leak detector.

16. The process chamber of claim 13, wherein the ground adapter further comprises a coolant channel disposed within the ground adapter.

17. The process chamber of claim 16, wherein the coolant channel of the ground adapter and the coolant channel of the cooled process tool adapter are fluidly coupled in series.

18. The process chamber of claim 13, further comprising a bias power source coupled to the cooled process tool adapter.

19. The process chamber of claim 18, wherein the body is grounded.

20. The process chamber of claim 19, further comprising a process tool coupled to the cooled process tool adapter, wherein the process tool is coupled to the bias power source via the cooled process tool adapter.
